(19) United States
(12) Patent Application Publication
(10) Pub. No.: US 2010/0031993 A1
(43) Pub. Date: Feb. 11, 2010

(54) THERMOELECTRIC CONVERSION MATERIAL AND THERMOELECTRIC CONVERSION DEVICE

(75) Inventors: Yoshio Uchida, Ibaraki (JP); Tetsuro Tohma, Ehime (JP); Kazuo Sadaoka, Osaka (JP)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: SUMITOMO CHEMICAL COMPANY, LIMITED, Chuo-ku, Tokyo (JP)

(21) Appl. No.: 12/513,574

(22) PCT Filed: Nov. 26, 2007
(86) PCT No.: PCT/JP2007/073262

§ 371 Date: Jun. 16, 2009

(30) Foreign Application Priority Data
Nov. 28, 2006 (JP) 2006-319695

(51) Int. Cl. H01L 35/12; B32B 18/00; C01F 17/00

(52) U.S. Cl. 136/236.1; 428/697; 423/263

(57) ABSTRACT

A thermoelectric conversion material is provided with stable thermoelectric conversion properties such as power factor in air at high temperature. The thermoelectric conversion material contains a mixed metal oxide comprising M¹, M^{2A} and M^{2B} as metal elements at a molar ratio of M¹:M^{2A}:M^{2B} of 2:1:1 and has a perovskite crystal structure, wherein M¹ represents at least one M^{1A} selected from the group consisting of La, Y and lanthanoid elements, or a combination of M^{1A} and at least one M^{1B} selected from among alkaline earth metal elements, M^{2A} represents at least one selected from the group consisting of metal elements each of which can have an atomic valence of 2, M^{2B} represents at least one selected from the group consisting of metal elements each of which can have an atomic valence of 4, M¹, M^{2A} and M^{2B} are different from one another, and each of M^{2A} and M^{2B} may contain a doping element.

### TECHNICAL FIELD

The present invention relates to a thermoelectric conversion material and a thermoelectric conversion device.

### BACKGROUND ART

Thermoelectric conversion power generation is power generation of converting thermal energy into electric energy, utilizing Seebeck effect by which thermal electromotive force is generated by applying a temperature difference between thermoelectric conversion materials. Thermoelectric conversion power generation is expected as environment-conservative electrical power generation since it is capable of utilizing earth's heat or exhaust heat such as heat from incinerators as a thermal energy.

An efficiency of converting thermal energy into electric energy of the thermoelectric conversion material (hereinafter, referred to as “energy conversion efficiency”) depends on figure of merit (Z) of the thermoelectric conversion material. The figure of merit (Z) is determined according to the equation (1) using the Seebeck coefficient (α), electric conductivity (σ) and thermal conductivity (κ) of the thermoelectric conversion material.

Z=α²×σ/κ (1)

If a thermoelectric conversion material having large figure of merit (Z) is used, a thermoelectric conversion device of excellent energy conversion efficiency is obtained. α²×σ in the equation (1) is called a power factor (PF), and larger this value of a thermoelectric conversion material, output becomes higher per unit temperature of a thermoelectric conversion device.

The thermoelectric conversion material includes a p-type thermoelectric conversion material having a positive Seebeck coefficient and an n-type thermoelectric conversion material having a negative Seebeck coefficient. Usually, a thermoelectric conversion device having a p-type thermoelectric conversion material and an n-type thermoelectric conversion material connected electrically serially is used, in thermoelectric conversion power generation. The energy conversion efficiency of the thermoelectric conversion device depends on the figure of merit (Z) of the p-type thermoelectric conversion material and the n-type thermoelectric conversion material. For obtaining a thermoelectric conversion device excellent in energy conversion efficiency, a p-type thermoelectric conversion material and an n-type thermoelectric conversion material having a large figure of merit (Z) are required.

For example, JP-A 2001-512910 (p. 2-8) discloses a thermoelectric conversion material represented by RBa₂Cu₃O_{7-δ}.

The thermoelectric conversion material described in this publication, however, does not have thermoelectric conversion properties (e.g., power factor) which are stable and excellent under operating ambient conditions of air at high temperature (approximately 600° C.).

### DISCLOSURE OF THE INVENTION

The present invention has an object of providing a material showing thermoelectric conversion properties which are stable and excellent under operating ambient conditions.

The present inventors have variously investigated and resultantly completed the present invention.

That is, the present invention provides a thermoelectric conversion material comprising a mixed metal oxide comprising M¹, M^{2A} and M^{2B} as metal elements at a molar ratio of M¹:M^{2A}:M^{2B} of 2:1:1 and having a perovskite crystal structure,

wherein M¹ represents at least one M^{1A} selected from the group consisting of La, Y and lanthanoid elements, or a combination of M^{1A} and at least one M^{1B} selected from among alkaline earth metal elements,

M^{2A} represents at least one selected from the group consisting of metal elements each of which can have an atomic valence of 2,

M^{2B} represents at least one selected from the group consisting of metal elements each of which can have an atomic valence of 4,

M¹, M^{2A} and M^{2B} are different from one another, and each of M^{2A} and M^{2B} may contain a doping element.

Further, the present invention provides a thermoelectric conversion device containing the above-described thermoelectric conversion material.

### BRIEF EXPLANATION OF DRAWING

FIG. 1 shows an X-ray diffraction pattern of a sintered body 1 in Example 1.

### MODES FOR CARRYING OUT THE INVENTION

### Thermoelectric Conversion Material

The thermoelectric conversion material of the present invention contains a mixed metal oxide. The mixed metal oxide contains M¹, M^{2A} and M^{2B} as metal elements.

M¹ is M^{1A}, or a combination of M^{1A} and M^{1B}. M^{1A} may be advantageously selected from the group consisting of La, Y and lanthanoid elements, and preferable are metal elements each of which can have an atomic valence of 3 among them. M^{1A} represents usually La, Y, Ce, Pr, Nd, Pm, Sm, Eu or Gd, preferably La. These may be used singly or in combination with another or more. M^{1B} represents an alkaline earth metal element, preferably Ca, Sr or Ba. These may be used singly or in combination with another or more. When M¹ is a combination of M^{1A} and M^{1B}, the amount of M^{1B} is usually 1:0.01 to 1:1 in terms of the molar ratio of M^{1A}:M^{1B}.

M^{2A} represents a metal element which can have an atomic valence of 2, preferably Cu, Ni, Zn or Ag, more preferably Cu. These may be used singly or in combination with another or more. M^{2A} may also be a combination of metal elements each of which can have an atomic valence of 2 and metal elements having an atomic valence of other than 2 (doping element I, for example, Li, Na, Al, Ga, In, Bi, Sb), and a part of the former may be substituted by the latter. A thermoelectric conversion material containing such a doping element I may have high thermoelectric conversion properties.

M^{2B} represents a metal element which can have an atomic valence of 4, preferably Ti, V, Cr, Mn, Fe, Co, Zr, Nb, Mo, Tc, Ru, Os, Ir, Pt, Au or Sn, more preferably Sn, Ti or Mn. These may be used singly or in combination with another or more. M^{2B} may also be a combination of metal elements each of which can have an atomic valence of 4 and metal elements having an atomic valence of other than 4 (doping element II, for example, Mg, Ca, Cu, Ni, Zn, Ag, Sc, Al, Ga, In, Bi, Sb), and a part of the former may be substituted by the latter. Also a thermoelectric conversion material containing such a doping element II may have high thermoelectric conversion properties, likewise.

M¹, M^{2A} and M^{2B} are different from one another. For example, when M¹ is a combination of M^{1A} and M^{1B}, M^{2A} does not contain a metal element M^{1B}. For example, when M^{2A} is divalent Sn, M^{2B} does not contain tetravalent Sn.

The molar ratio of M¹:M^{2A}:M^{2B} is 2:1:1.

The mixed metal oxide has a perovskite crystal structure.

Specific examples of the mixed metal oxide are shown below. Examples of the mixed metal oxide in which M^{1A} is La include:

### La₂CuSnO₆ (M^{2A} is Cu, M^{2B} is Sn),

### La₂CuTiO₆ (M^{2A} is Cu, M^{2B} is Ti),

### La₂NiSnO₆ (M^{2A} is Ni, M^{2B} is Sn),

### La₂ZnSnO₆ (M^{2A} is Zn, M^{2B} is Sn),

### La₂ZnTiO₆ (M^{2A} is Zn, M^{2B} is Ti),

### La₂ZnZrO₆ (M^{2A} is Zn, M^{2B} is Zr),

La₂₋ₓCaₓCu₂Sn₂O₁₁ (M^{1B} is Ca, M^{2A} is Cu, M^{2B} is Sn, 0.01≦x/(2-x)≦1),
La₂₋ₓCaₓCu₂Ti₂O₁₁ (M^{1B} is Ca, M^{2A} is Cu, M^{2B} is Ti, 0.01≦x/(2-x)≦1),
La₂₋ₓCaₓZn₂Sn₂O₁₁ (M^{1B} is Ca, M^{2A} is Zn, M^{2B} is Sn, 0.01≦x/(2-x)≦1),
La₂₋ₓCaₓZn₂Ti₂O₁₁ (M^{1B} is Ca, M^{2A} is Zn, M^{2B} is Ti, 0.01≦x/(2-x)≦1),
La₂₋ₓCaₓNi₂Sn₂O₁₁ (M^{1B} is Ca, M^{2A} is Ni, M^{2B} is Sn, 0.01≦x/(2-x)≦1)
La₂₋ₓBaₓCu₂Sn₂O₁₁ (M^{1B} [symbol] Ba, M^{2A} is Cu, M^{2B} is Sn, 0.01≦x/(2-x)≦1),
La₂₋ₓBaₓCu₂Ti₂O₁₁ (M^{1B} [symbol] Ba, M^{2A} is Cu, M^{2B} is Ti, 0.01≦x/(2-x)≦1),
La₂₋ₓBaₓZn₂Sn₂O₁₁ (M^{1B} [symbol] Ba, M^{2A} is Zn, M^{2B} is Sn, 0.01≦x/(2-x)≦1),
La₂₋ₓBaₓZn₂Ti₂O₁₁ (M^{1B} [symbol] Ba, M^{2A} is Zn, M^{2B} is Ti, 0.01≦x/(2-x)≦1),
La₂₋ₓBaₓNi₂Sn₂O₁₁ (M^{1B} [symbol] Ba, M^{2A} is Ni, M^{2B} is Sn, 0.01≦x/(2-x)≦1),
La₂₋ₓSrₓCu₂Sn₂O₁₁ (M^{1B} is Sr, M^{2A} is Cu, M^{2B} is Sn, 0.01≦x/(2-x)≦1),
La₂₋ₓSrₓCu₂Ti₂O₁₁ (M^{1B} is Sr, M^{2A} is Cu, M^{2B} is Ti, 0.01≦x/(2-x)≦1),
La₂₋ₓSrₓZn₂Sn₂O₁₁ (M^{1B} is Sr, M^{2A} is Zn, M^{2B} is Sn, 0.01≦x/(2-x)≦1),
La₂₋ₓSrₓZn₂Sn₂O₁₁ (M^{1B} is Sr, M^{2A} is Zn, M^{2B} is Ti, 0.01≦x/(2-x)≦1),
La₂₋ₓSrₓNi₂Sn₂O₁₁ (M^{1B} is Sr, M^{2A} is Ni, M^{2B} is Sn, 0.01≦x/(2-x)≦1),

The mixed metal oxide in which ML represents a metal element which can have an atomic valence of 3 other than La (Y, Ce, Pr, Nd, Pm, Sm, Eu, Gd) is an oxide obtained by substituting La by these metal elements, and examples of the mixed metal oxide in which M^{1A} is Eu include:

### Eu₂CuSnO₆ (M^{2A} is Cu, M^{2B} is Sn)

### Eu₂CuTiO₆ (M^{2A} is Cu, M^{2B} is Ti)

### Eu₂NiSnO₆ (M^{2A} is Ni, M^{2B} is Sn)

### Eu₂ZnSnO₆ (M^{2A} is Zn, M^{2B} is Sn)

### Eu₂ZnTiO₆ (M^{2A} is Zn, M^{2B} is Ti)

### Eu₂ZnZrO₆ (M^{2A} is Zn, M^{2B} is Zr)

### Eu₂Ba₂Cu₂Sn₂O₁₁ (M^{1B} is Ba, M^{2A} is Cu, M^{2B} is Sn)

### Eu₂Ba₂Cu₂Ti₂O₁₁ (M^{1B} is Ba, M^{2A} is Cu, M^{2B} is Ti)

### Eu₂Ba₂Zn₂Sn₂O₁₁ (M^{1B} is Ba, M^{2A} is Zn, M^{2B} is Sn)

### Eu₂Ba₂Zn₂Ti₂O₁₁ (M^{1B} is Ba, M^{2A} is Zn, M^{2B} is Ti)

### Eu₂Ba₂Ni₂Sn₂O₁₁ (M^{1B} is Ba, M^{2A} is Ni, M^{2B} is Sn).

Y, Ce, Pr, Nd, Pm, Sm, Eu and Gd can be used in substitution as described above since each of them can have an atomic valence of 3 and has an ion radius which is approximately the same as that of La, and the resultant thermoelectric conversion material also performs an analogous effect.

Examples of the mixed metal oxide in which 40% of La is substituted by Eu include:

(La_{0.6}Eu_{0.4})₂CuSnO₆, (La_{0.6}Eu_{0.4})₂CuTiO₆, (La_{0.6}Eu_{0.4})₂NiSnO₆, (La_{0.6}Eu_{0.4})₂ZnSnO₆, (La_{0.6}Eu_{0.4})₂ZnTiO₆, (La_{0.6}Eu_{0.4})₂ZnZrO₆, (La_{0.6}Eu_{0.4})₂Ba₂Cu₂Sn₂O₁₁, (La_{0.6}Eu_{0.4})₂Ba₂Cu₂Ti₂O₁₁, (La_{0.6}Eu_{0.4})₂Ba₂Zn₂Sn₂O₁₁, (La_{0.6}Eu_{0.4})₂Ba₂Zn₂Ti₂O₁₁, (La_{0.6}Eu_{0.4})₂Ba₂Ni₂Sn₂O₁₁.

The thermoelectric conversion material has a form of, for example, powder, sintered body or thin film, and preferably sintered body. When the form of the thermoelectric conversion material is a sintered body, it is advantageous that the shape and dimension thereof are appropriate as a thermoelectric conversion device, and the shape is, for example, plate, circular cylinder or rectangular cylinder.

The thermoelectric conversion material is preferably a dense material from the standpoint of electric conductivity (a) and mechanical strength, and the relative density thereof is preferably not less than 60%, more preferably not less than 80%, further preferably not less than 90%. Such a thermoelectric conversion material has typically a shape of oriented sintered body or single crystal.

When thermoelectric conversion material has a possibility of showing decrease in performance by oxidation or reduction under operating ambient conditions, its surface may be coated with a gas barrier film. The gas barrier film is composed of, for example, alumina, titania, zirconia, or silicon carbide. The gas barrier film is advantageously one which covers the surface or part thereof within the range not deteriorating the function of the thermoelectric conversion material.

The thermoelectric conversion material of the present invention may be advantageously produced by a sintering method, and for example, it may be advantageously produced by a method in which a mixture of metals or metal oxides is sintered. The mixture may be advantageously prepared by a method in which metals or metal compounds are weighed and mixed so as to provide a given composition.

The thermoelectric conversion material may be advantageously produced, specifically, by a method in which a compound containing M¹, a compound containing M^{2A} and a metal compound containing M^{2B} are weighed and mixed to prepare a mixture satisfying the molar ratio of M¹:M^{2A}:M^{2B} of 2:1:1, and the mixture is sintered, and the mixed metal oxide represented by Y₂CuSnO₆ may be advantageously produced by a method in which yttrium oxide (Y₂O₃), copper oxide (CuO) and tin oxide (SnO₂) are used as metal compounds, and these compounds are weighed and mixed so that the molar ratio of Y:Cu:Sn satisfies 2:1:1, to obtain a mixture and the mixture is sintered.

The metal compound is a compound containing a metal element represented by M¹, M^{2A} or M^{2B}, and examples thereof include hydroxides, carbonates, nitrates, halides, sulfates and organic acid salts which are decomposed and/or oxidized at high temperature to become oxides, or oxides.

The thermoelectric conversion material may also be produced, for example, by a method in which a compound containing M^{1A}, a compound containing M^{2A} and a metal compound containing M^{2B} are weighed and mixed to prepare a mixture satisfying the molar ratio of M^{1A}:M^{2A}:M^{2B} of 2:1:1, and the mixture is sintered, and in this case, M^{1A} is La, M^{2A} is Cu and M^{2B} is Sn. The compound containing La is, for example, lanthanum oxide, lanthanum hydroxide or lanthanum nitrate, preferably, lanthanum oxide. The compound containing Cu is, for example, copper(I) oxide, copper(II) oxide or copper nitrate, preferably, copper(II) oxide, and the compound containing Sn is, for example, tin oxide, tin nitrate or tin chloride, preferably, tin oxide.

It is advantageous that the mixing is carried out using, for example, ball mill, V-shape mixer, vibration mill, attritor, dyno mill or dynamic mill. The mixing may be carried out either in dry mode or wet mode. The mixing is preferably carried out by a method for obtaining a uniform mixture of metal oxides from the standpoint of obtaining an excellent thermoelectric conversion material.

The mixture may contain additives such as a binder, dispersant and releasing agent. The additive may be added in mixing the compound, or may be added to the mixture, or a sintered body or pulverized body described later. The mixture may be, if necessary, calcined. When the mixture contains hydroxides, carbonates, nitrates, halides, organic acid salts and the like which are decomposed and/or oxidized at high temperature to become oxides, the calcination can be carried out, to change them into oxides, or remove a carbon dioxide gas and crystal water from them, further, to improve uniformity of the composition of the sintered body or uniformity of the structure of the sintered body, and to suppress deformation of the sintered body. The calcination may be advantageously carried out by setting conditions appropriately depending on the composition of the mixture, and for example, when the mixture contains a carbonate, the calcination may be advantageously carried out under conditions of temperature: not less than 600° C. and not more than 1200° C., atmosphere: air, holding time: 5 to 24 hours. The mixture may be pulverized. The pulverizing may be advantageously carried out using, for example, ball mill, vibration mill, attritor, dyno mill or dynamic mill. The mixture may be formed. The formation may be advantageously carried out under conditions giving a shape suitable as a thermoelectric conversion device, such as plate, rectangular cylinder, and circular cylinder. The formation may be advantageously carried out using, for example, uniaxial press, cold isostatic press (CIP), mechanical press, hot press or hot isobaric press (HIP).

The thermoelectric conversion material is preferably produced by a method in which a mixture, calcined body or pulverized body is formed, and the resultant is sintered, and further preferably produced by a method in which a mixture is calcined, pulverized, then, formed, and the resultant is sintered.

The sintering may be advantageously carried out under conditions of temperature: not less than 700° C. and not more than 1700° C., preferably not less than 900° C. and not more than 1500° C., further preferably not less than 1000° C. and not more than 1400° C., holding time: 0.5 to 48 hours, and atmosphere: air, oxygen, vacuum or inert gas (nitrogen, rare gas). When the sintering temperature is less than 700° C., sintering is difficult, and depending on the composition of the mixed metal oxide, the electric conductivity (σ) of thermoelectric conversion material may decrease. In contrast, when the sintering temperature is over 1500° C., abnormal grain growth and melting occur, and the figure of merit (Z) of the thermoelectric conversion material may decrease, depending on the composition of the mixed metal oxide.

The sintered body may be pulverized, if necessary, and the pulverized body may be sintered. The sintering may be advantageously carried out under the same conditions as described above.

The thermoelectric conversion material may be advantageously produced by a method in which the mixture is calcined and pulverized, and the resultant pulverized body is formed and sintered simultaneously by HIP.

In the production of the thermoelectric conversion material, the relative density of the sintered body can be controlled by altering the particle size of a mixture, calcined body or pulverized body, or molding pressure, sintering temperature, sintering time and the like.

When thermoelectric conversion material has a possibility of showing decrease in performance by oxidation or reduction under operating ambient conditions, its surface may be coated with a gas barrier film through which a gas does not permeate easily. The gas barrier film is composed of, for example, alumina, titania, zirconia, or silicon carbide. The coating may be advantageously carried out by, for example, aerosol deposition, thermal spray or CVD (chemical vapor deposition).

Thermoelectric conversion material may also be produced by other methods. Examples of the other methods include methods including a co-precipitation step, a hydrothermal step, a dry up step, a sputtering step, a step of CVD, a sol gel step, a FZ (floating zone melting) step or a step of TSCG (template type single crystal growth).

### Thermoelectric Conversion Device

The thermoelectric conversion device contains the above-described thermoelectric conversion material.

Since the thermoelectric conversion material is usually p-type, the thermoelectric conversion device contains the p-type thermoelectric conversion material and an n-type thermoelectric conversion material. As the n-type thermoelectric conversion material, for example, Zn_{0.98}Al_{0.2}O or SrTiO₃ may be used (see, JP-A 8-186293, JP-A 8-231223). The thermoelectric conversion device may be advantageously fabricated so as to give a structure disclosed, for example, in JP-A 5-315657.

### EXAMPLES

The present invention will be illustrated further in detail by examples, but the scope of the present invention is not limited to them. The properties of the thermoelectric conversion material were measured as follows.

### Crystal Structure

The crystal structure of a sample (calcined body, sintered body) was determined by powder X-ray diffractometry using an X-ray diffractometer (trade name: RINT2500TTR, manufactured by Rigaku Corporation) with a radiation source: CuKα.

### Seebeck Coefficient (α, μV/K)

A sample (sintered body) was processed into rectangular cylinder to obtain a specimen. A R thermocouple and platinum line were provided on the both ends of the specimen, using a silver paste, and the temperatures of the specimen and the thermal electromotive force were measured in air at room temperature to 1073 K. A glass tube through which air was flowing was brought into contact with one end surface of the specimen to cool the specimen to make a low temperature part. At this stage, the temperatures of the both end surfaces were measured by the R thermocouple, and simultaneously, the thermal electromotive force (ΔV) generated between the both end surfaces of the specimen was measured. The temperature difference (ΔT) between the both ends of the specimen was controlled in the range of 1 to 10° C. by controlling the flow rate of air. The Seebeck coefficient (α) was calculated from inclinations of ΔT and ΔV.

### Electric Conductivity (σ, S/m)

A platinum line was provided on a specimen using a silver paste, the specimen being obtained by the same manner as for measurement of Seebeck coefficient, and the electric conductivity was measured by a direct current four-point probe method in air at room temperature to 1073 K.

### Thermal Conductivity (κ, W/mK)

The thermal conductivity of a sample (sintered body) was measured by a laser flushing method using a thermal conductivity measurement apparatus (trade name: TC-7000, manufactured by Sinku-Riko Inc.) at room temperature (measurement temperature).

### Relative Density (%)

The relative density of a sample (sintered body) was determined by the Archimedes method.

### Example 1

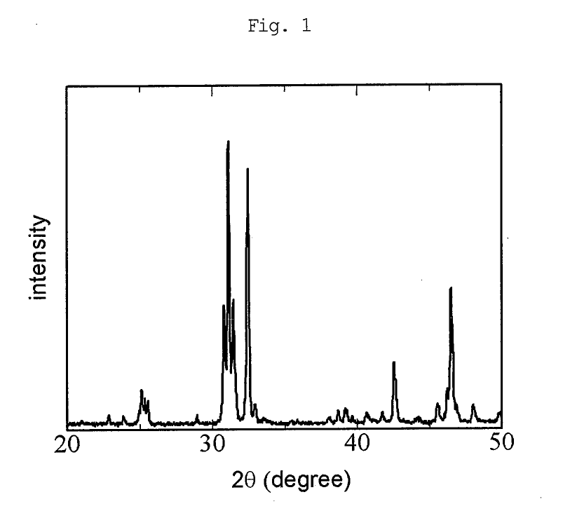

3.074 g of CuO (Manufactured by Kojundo Chemical Laboratory Co., Ltd.), 5.825 g of SnO₂ (Manufactured by Kojundo Chemical Laboratory Co., Ltd.) and 12.593 g of La₂O₃ (Manufactured by Kojundo Chemical Laboratory Co., Ltd.) were weighed and mixed for 20 hours using a wet ball mill with zirconia ball media. The mixture was calcined in air at 1100° C. for 24 hours and pulverized for 20 hours using a wet ball mill with zirconia ball media to obtain a powder. The powder was formed using a uniaxial press (molding pressure: 1000 kg/cm²) to obtain a disk-shaped green body. The green body was sintered for 24 hours under an atmosphere of 100% oxygen at 1100° C. to obtain a sintered body 1. The properties of the sintered body 1 were shown in Table 1. The X-ray diffraction pattern of the sintered body 1 was shown in FIG. 1. The sintered body 1 had a relative density of 95%, and a thermal conductivity at room temperature (approximately 25° C.) of 5.61 W/mK.

### Example 2

The same operation as in Example 1 was carried out excepting that 1.537 g of CuO (Manufactured by Kojundo Chemical Laboratory Co., Ltd.), 2.912 g of SnO₂ (Manufactured by Kojundo Chemical Laboratory Co., Ltd.), 6.139 g of La₂O₃ (Manufactured by Kojundo Chemical Laboratory Co., Ltd.) and 0.097 g of CaCO₃ (trade name: CS3N-A, manufactured by Ube Material Industries) were used as raw materials, to obtain a sintered body 2. The properties of the sintered body 2 were shown in Table 1. The sintered body 2 had a thermal conductivity at room temperature (approximately 25° C.) of 3.63 W/mK.

### Example 3

The same operation as in Example 1 was carried out excepting that 1.537 g of CuO (Manufactured by Kojundo Chemical Laboratory Co., Ltd.), 2.912 g of SnO₂ (Manufactured by Kojundo Chemical Laboratory Co., Ltd.), 6.139 g of La₂O₃ (Manufactured by Kojundo Chemical Laboratory Co., Ltd.) and 0.191 g of BaCO₃ (trade name: LC-1, manufactured by Nippon Chemical Industrial Co., Ltd.) were used as raw materials to obtain a sintered body 3. The properties of the sintered body 3 were shown in Table 1. The sintered body 3 had a thermal conductivity at room temperature (approximately 25° C.) of 3.30 W/mK.

### Example 4

The same operation as in Example 1 was carried out excepting that 1.537 g of CuO (Manufactured by Kojundo Chemical Laboratory Co., Ltd.), 2.912 g of SnO₂ (Manufactured by Kojundo Chemical Laboratory Co., Ltd.), 6.139 g of La₂O₃ (Manufactured by Kojundo Chemical Laboratory Co., Ltd.) and 0.143 g of SrCO₃ (trade name: SW-K, manufactured by Sakai Chemical Industry Co., Ltd.) were used as raw materials to obtain a sintered body 4. The properties of the sintered body 4 were shown in Table 1.

### Example 5

The same operation as in Example 1 was carried out excepting that 1.537 g CuO of (Manufactured by Kojundo Chemical Laboratory Co., Ltd.), 2.767 g of SnO₂ (Manufactured by Kojundo Chemical Laboratory Co., Ltd.), 6.297 g of La₂O₃ (Manufactured by Kojundo Chemical Laboratory Co., Ltd.) and 0.039 g of MgO (Manufactured by Wako Pure Chemical Industries Ltd.) were used as raw materials to obtain a sintered body 5. The properties of the sintered body 5 were shown in Table 1.

TABLE 1
Properties of sintered body

| | | | crystal |
|---|---|---|---|
| | | metal element ratio | structure |
| Example 1 | Sintered body 1 | La:Cu:Sn = 2:1:1 | perovskite |
| Example 2 | Sintered body 2 | La:Ca:Cu:Sn = 1.95:0.05:1:1 | perovskite |
| Example 3 | Sintered body 3 | La:Ba:Cu:Sn = 1.95:0.05:1:1 | perovskite |
| Example 4 | Sintered body 4 | La:Sr:Cu:Sn = 1.95:0.05:1:1 | perovskite |
| Example 5 | Sintered body 5 | La:Cu:Sn:Mg = 2:1:0.95:0.05 | perovskite |

| | | 473 K | | |
|---|---|---|---|---|
| | | Seebeck | electric | power |
| | | coefficient | conductivity | factor |
| | | μV/K | S/m | W/mK² |
| Example 1 | sintered body 1 | 615 | 3.3 | 1.2 × 10⁻⁶ |
| Example 2 | sintered body 2 | 271 | 2.2 × 10² | 1.6 × 10⁻⁵ |
| Example 3 | sintered body 3 | 240 | 2.5 × 10² | 1.4 × 10⁻⁵ |
| Example 4 | sintered body 4 | 213 | 4.0 × 10² | 1.8 × 10⁻⁵ |
| Example 5 | sintered body 5 | 441 | 3.8 × 10¹ | 7.4 × 10⁻⁶ |
| | | 873 K | | |
| | | Seebeck | electric | power |
| | | coefficient | conductivity | factor |
| | | μV/K | S/m | W/mK² |
| Example 1 | sintered body 1 | 348 | 1.9 × 10¹ | 2.3 × 10⁻⁶ |
| Example 2 | sintered body 2 | 166 | 4.6 × 10² | 1.3 × 10⁻⁵ |
| Example 3 | sintered body 3 | 171 | 4.8 × 10² | 1.4 × 10⁻⁵ |
| Example 4 | sintered body 4 | 135 | 6.9 × 10² | 1.3 × 10⁻⁵ |
| Example 5 | sintered body 5 | 296 | 1.2 × 10² | 1.3 × 10⁻⁵ |

### INDUSTRIAL APPLICABILITY

According to the present invention, a thermoelectric conversion material with stable thermoelectric conversion properties such as power factor in air at high-temperature is provided. The thermoelectric conversion material is useful for thermoelectric conversion power generation which is expected as environment-conservative electrical power generation.

1. A thermoelectric conversion material comprising a mixed metal oxide comprising M¹, M^{2A} and M^{2B} as metal elements at a molar ratio of M¹:M^{2A}:M^{2B} of 2:1:1 and having a perovskite crystal structure,
wherein M¹ represents at least one M^{1A} selected from the group consisting of La, Y and lanthanoid elements, or a combination of M^{1A} and at least one M^{1B} selected from among alkaline earth metal elements,
M^{2A} represents at least one selected from the group consisting of metal elements each of which can have an atomic valence of 2,
M^{2B} represents at least one selected from the group consisting of metal elements each of which can have an atomic valence of 4,
M¹, M^{2A} and M^{2B} are different from one another, and each of M^{2A} and M^{2B} may contain a doping element.

2. The material according to claim 1, wherein M^{1A} represents at least one selected from the group consisting of La, Y, Ce, Pr, Nd, Pm, Sm, Eu and Gd.

3. The material according to claim 2, wherein M^{1A} represents La.

4. The material according to claim 1, wherein M^{2A} represents at least one selected from the group consisting of Cu, Ni, Zn and Ag.

5. The material according to claim 4, wherein M^{2A} represents Cu.

6. The material according to claim 1, wherein M^{2B} represents at least one selected from the group consisting of Ti, V, Cr, Mn, Fe, Co, Zr, Nb, Mo, Tc, Ru, Os, Ir, Pt, Au and Sn.

7. The material according to claim 6, wherein M^{2B} represents at least one selected from the group consisting of Sn, Ti and Mn.

8. The material according to claim 1, wherein the material has a shape of sintered body and has a relative density of not less than 60%.

9. The material according to claim 8, wherein its surface is coated with a gas barrier film.

10. A thermoelectric conversion device comprising the material as described in claim 1.
